(19) United States
(12) Patent Application Publication
(10) Pub. No.: US 2007/0228552 A1
(43) Pub. Date: Oct. 4, 2007

(54) Optical semiconductor device provided with phase control function

(75) Inventors: Takeshi Takeuchi, Tokyo (JP); Hiroyuki Yamazaki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC CORPORATION, Tokyo (JP)

(21) Appl. No.: 11/727,558

(22) Filed: Mar. 27, 2007

(30) Foreign Application Priority Data
Mar. 28, 2006 (JP) 2006-088601

(51) Int. Cl. H01L 33/00; H01L 23/053; H01L 23/14; H01L 31/12; H01L 29/22; H01L 23/12

(52) U.S. Cl. 257/702; 257/79; 257/98; 257/701

(57) ABSTRACT

An optical semiconductor device has an optical semiconductor element; and a mounting substrate unit on which the optical semiconductor element is mounted, wherein the optical semiconductor element has an element substrate 14 and an active layer 17 formed on a lower side surface of the element substrate, the mounting substrate unit has a mounting substrate 23 and a heater electrode 8 arranged on an upper side surface of the mounting substrate. The optical semiconductor element is arranged such that the lower side surface of the element substrate 14 on which the active layer 17 is formed faces the upper side surface of the mounting substrate 23 on which the heater electrode 8 is arranged, and the active layer 17 is to be heated due to the heat-generation by the heater electrode 8. A p-electrode 10 of the mounting substrate unit and a p-electrode 19 of the optical semiconductor element are bonded to each other using a conductive fusion bonding member 20.

### BACKGROUND OF THE INVENTION

1. Field of the Invention

The present invention relates to an optical semiconductor device provided with a function of controlling the phase of a light, and more particularly, to an optical semiconductor device that is adapted to control the phase of a light in an optical semiconductor element mounted on a mounting substrate by using a phase control means provided on the mounting substrate.

2. Description of Related Art

In a wavelength-variable light source configuring a wavelength division multiplexing (WDM) transmission system in the field of optical communication, the phase of a light in an optical semiconductor element is controlled. The wavelength-variable light source, which can oscillate a plurality of wavelengths, is significantly useful as a light source for a WDM transmission system as regarding the point that the reconstitution of system is simplified and that the stock of backup light sources can be reduced, and has been actively researched and developed.

An example of a wavelength-variable optical semiconductor device that is such a wavelength-variable light source and belongs to the technology related to the present invention is shown in FIG. 9 and FIG. 10. FIG. 9 shows a schematic plan view of the wavelength-variable optical semiconductor device, while FIG. 10 shows a schematic sectional view of the wavelength-variable optical semiconductor device of FIG. 9 taken along a A-A′ line.

This wavelength-variable optical semiconductor device includes a semiconductor optical amplifier (SOA) 101 and a ring resonator type wavelength filter 102. The ring resonator type wavelength filter 102 includes a plurality of ring resonators 103 whose optical path lengths are slightly different from each other, heaters 104 which control the temperature of the ring resonators 103, connection waveguides 105 which connect the ring resonators 103 serially or which are connected to end ring resonators 103, and a high reflection film 106 which is arranged at the end of the first end connection waveguide 105. The ring resonator type wavelength filter 102 is an optical circuit provided with a function of returning, among lights coming from the SOA 101 to the end of the second end connection waveguide 105 located at the opposite side of the first end connection waveguide 105, only a light of a specific wavelength to the SOA 101. This “specific wavelength” can be controlled by the heaters 104. The details of the ring resonator type wavelength filter 102 are disclosed in Non-patent Document 1 (2005 IEICE Electronics Society convention preprints, preprint No. C-3-89, written by Hiroyuki Yamazaki, and others) etc., and explanation of the ring resonator type wavelength filter are omitted here.

As shown in FIG. 9 and FIG. 10, the SOA 101 includes a gain region 107 and a phase control region 108. The gain region 107 obtains a gain for oscillation when a current is applied to an active layer 112 thereof. The phase control region 108 has its refraction index changed when a current is applied to a core layer 113 thereof, and controls the phase of a light so as to obtain the most favorable oscillation characteristics. This SOA 101 provided with the phase control region 108 is called a SOA provided with phase control region. In FIG. 10, reference numeral 116 indicates a semiconductor substrate, reference numeral 115 indicates a lower cladding layer, reference numeral 111 indicates an upper cladding layer, reference numeral 109 indicates the p-electrode of the gain region 107, reference numeral 110 indicates the p-electrode of the phase control region 108, and reference numeral 117 indicates the n-electrode.

The core layer 113 of the phase control region 108 is formed by a semiconductor layer configured by compositions (shorter wavelength compositions) different from those of the active layer 112 of the gain region 107 so as not to raise a loss with respect to the oscillation wavelength. The active layer 112 and core layer 113 are formed by the etching process and the re-growing process respectively, and are coupled by a so-called butt joint 114. Outgoing light from the edge of the phase control region 108 goes to the end of the second end connection waveguide 105 of the ring resonator type wavelength filter 102, while an outgoing light from the edge of the gain region 107 is taken out to the outside as an output light (light output) of a wavelength-variable light source.

On the other hand, in Patent Document 1 (JP-A-2003-23208), there is disclosed a wavelength-variable semiconductor laser of the heater electrode integration type which is different from that using the phase control region having the core layer coupled to the active layer of the gain region by the butt joint.

Furthermore, in Patent Document 2 (JP-A-2005-529498), there is disclosed a wavelength-variable light source provided with a heating device such as a thermoelectric element or resistor that changes the optical path length by heating a gain element.

However, the wavelength-variable optical semiconductor device of the related technology shown in FIG. 9 and FIG. 10 has some problems. The first problem is that the light is reflected at the butt joint 114 of the SOA 101 having the phase control region, and thus raised reflected light is returned to the gain region 107, making the oscillation characteristics unstable. The second problem is that the butt joint 114 of the SOA 101 having the phase control region is low in yield ratio in producing elements, making the element production cost high.

According to the wavelength-variable semiconductor laser disclosed in the Patent Document 1, heater electrodes are integrated into a semiconductor laser element, and, in case there is raised a defect in the heater electrodes, the entire semiconductor laser element comes to be a defective product, often raising the lowering in the production yield ratio due to the heater electrodes.

According to the wavelength-variable light source disclosed in the Patent Document 2, even if the light source is provided with a heating device, the structural relationship between the heating device and the gain element is not specified.

### SUMMARY OF THE INVENTION

It is therefore an object of the present invention to overcome the above-mentioned drawbacks by providing an optical semiconductor device provided with the phase control function which is stable in oscillation characteristics, which can improve the production yield ratio, and which can realize a wavelength-variable light source enabling cost reduction.

According to the present invention, to attain the above object, there is provided an optical semiconductor device comprising:

an optical semiconductor element; and

a mounting substrate unit on which the optical semiconductor element is mounted,

wherein the optical semiconductor element has an element substrate and an active layer formed on one side surface of the element substrate, the mounting substrate unit has a mounting substrate and a heat-generation/heat-absorption function unit arranged on one side surface of the mounting substrate, and the optical semiconductor element is arranged such that the one side surface of the element substrate on which the active layer is formed faces the one side surface of the mounting substrate on which the heat-generation/heat-absorption function unit is arranged, and the active layer is to be heated/cooled due to the heat-generation/heat-absorption by the heat-generation/heat-absorption function unit.

In an aspect of the present invention, the optical semiconductor element is bonded to the mounting substrate unit. In an aspect of the present invention, the optical semiconductor device further comprises a spacer arranged between the optical semiconductor element and the mounting substrate unit. In an aspect of the present invention, the heat-generation/heat-absorption function unit is formed of a metal thin film.

In an aspect of the present invention, the active layer extends along the one side surface of the element substrate, the heat-generation/heat-absorption function unit has an extension portion that extends along the one side surface of the mounting substrate, and the active layer and the extension portion of the heat-generation/heat-absorption function unit have their extension directions made parallel with each other and are arranged at positions corresponding to each other.

In an aspect of the present invention, the mounting substrate unit comprises an insulating layer formed on the heat-generation/heat-absorption function unit, and a mounting substrate electrode of a first polarity formed on the insulating layer. In an aspect of the present invention, the mounting substrate electrode of the first polarity has a portion that extends in parallel with the extension portion of the heat-generation/heat-absorption function unit. In an aspect of the present invention, the optical semiconductor element comprises a lower cladding layer formed on the one side surface of the element substrate, the active layer being formed on the lower cladding layer, and an upper cladding layer formed on the active layer, and an element electrode of a first polarity formed on the upper cladding layer so as to extend in parallel with the active layer, and wherein the element electrode of the first polarity and the mounting substrate electrode of the first polarity are bonded to each other using a conductive bonding member.

In an aspect of the present invention, the optical semiconductor device further comprises a heat-generation/heat-absorption amount adjustment means for adjusting the heat-generation/heat-absorption amount of the heat-generation/heat-absorption function unit. In an aspect of the present invention, the heat-generation/heat-absorption amount adjustment means is provided with an electric resistance value measurement means for measuring the electric resistance value of the heat-generation/heat-absorption function unit, and adjusts the heat-generation/heat-absorption amount of the heat-generation/heat-absorption function unit based on the electric resistance value of the heat-generation/heat-absorption function unit measured by the electric resistance value measurement means.

In an aspect of the present invention, the mounting substrate unit has an optical circuit provided with a reflection function of returning a light emitted from the optical semiconductor element to the optical semiconductor element. In an aspect of the present invention, the optical circuit is provided with the reflection function only for a light of a selected wavelength. In an aspect of the present invention, the mounting substrate unit is provided with a means for controlling the selected wavelength. In an aspect of the present invention, the optical circuit is formed on the mounting substrate. In an aspect of the present invention, the optical circuit is formed on an additional substrate different from the mounting substrate, and the additional substrate is bonded to the mounting substrate. In an aspect of the present invention, the mounting substrate is a silicon substrate.

According to the present invention, based on the above-described configuration, there is provided an optical semiconductor device provided with the phase control function which is stable in oscillation characteristics, which can improve the production yield ratio, and which can realize a wavelength-variable light source enabling cost reduction.

### BRIEF EXPLANATION OF THE DRAWINGS

FIG. 1 shows a schematic plan view indicative of the entire configuration of an embodiment of a optical semiconductor device provided with the phase control function according to the present invention;

FIG. 2 shows an enlarged view of a part enclosed by a dotted line in FIG. 1;

FIG. 3 shows a view indicative of the state in which an optical semiconductor element is removed in FIG. 2;

FIG. 4 shows schematic sectional view taken along A-A′ line in FIG. 2;

FIG. 5 shows schematic sectional view taken along B-B′ line in FIG. 2;

FIG. 6 shows schematic sectional view taken along C-C′ line in FIG. 2;

FIG. 7 shows a block diagram indicative of the configuration of an electric resistance value measurement means and a heat-generation/heat-absorption amount adjustment means;

FIG. 8 shows a schematic plan view indicative of the entire configuration of another embodiment of a optical semiconductor device provided with the phase control function according to the present invention;

FIG. 9 shows a schematic plan view of a wavelength-variable optical semiconductor device; and

FIG. 10 shows a schematic sectional view taken along a A-A′ line in FIG. 9.

### DETAILED DESCRIPTION OF THE PREFERRED EMBODIMENTS

Embodiments of the present invention will further be described below with reference to the accompanying drawings.

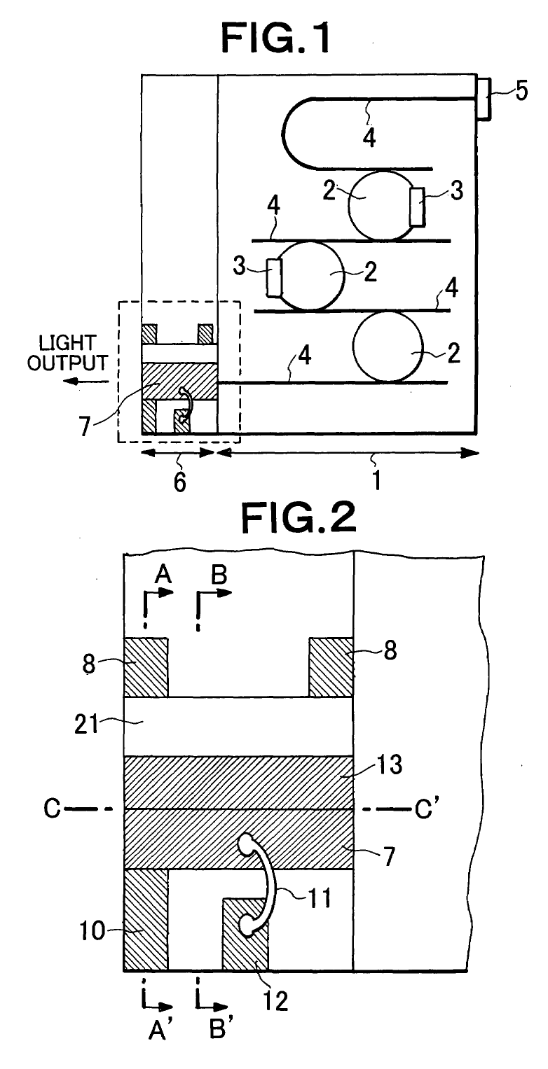

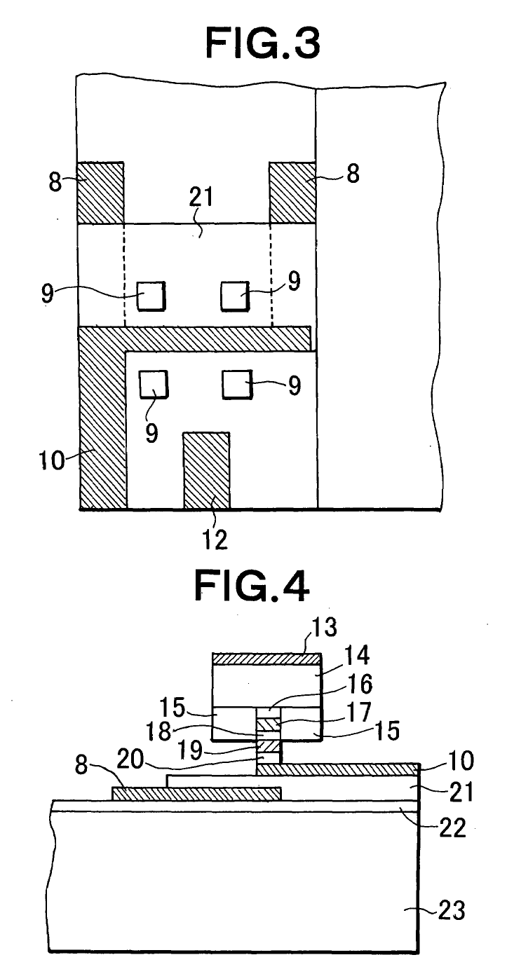

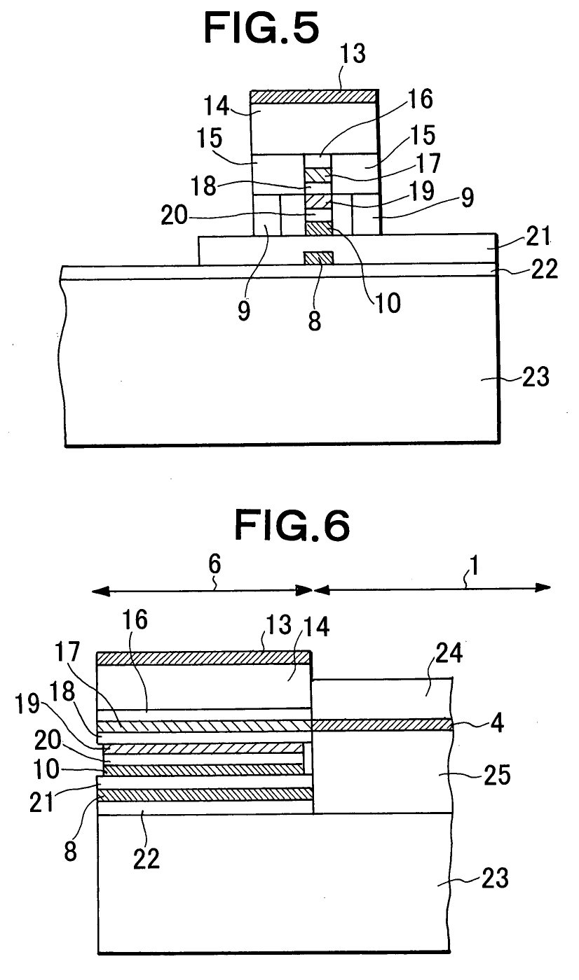

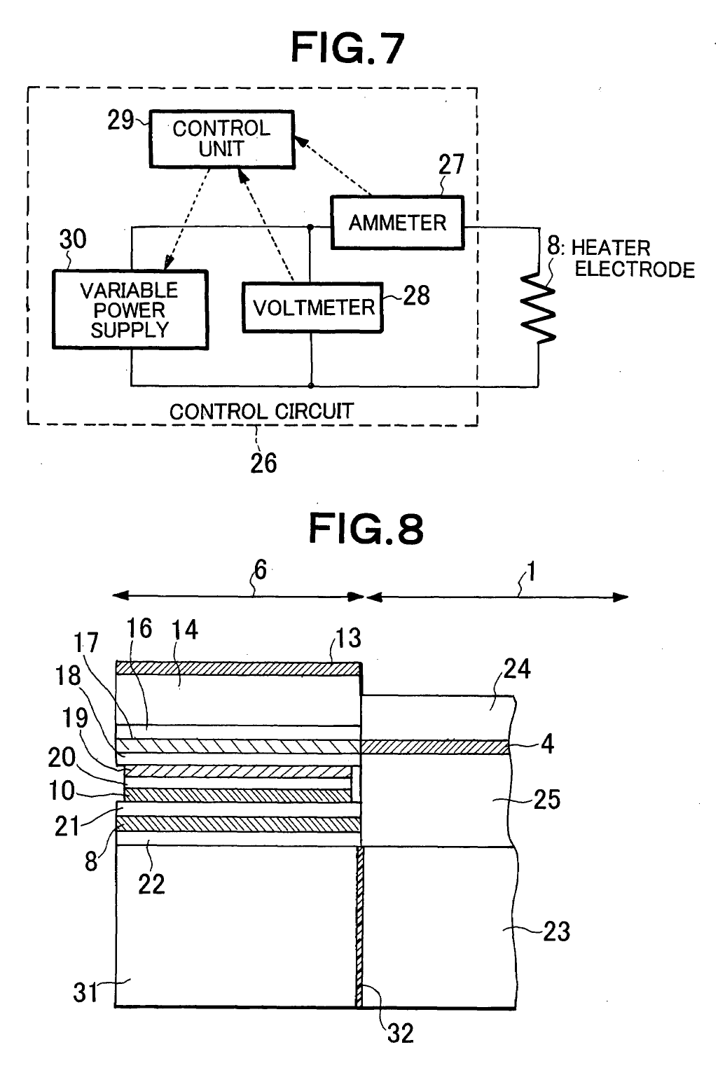

FIG. 1 to FIG. 7 show views for explaining the first embodiment of an optical semiconductor device provided with the phase control function according to the present invention. FIG. 1 shows a schematic plan view indicative of the entire configuration in this embodiment, FIG. 2 shows an enlarged view of a part enclosed by a dotted line in FIG. 1, FIG. 3 shows a view indicative of the state in which an optical semiconductor element is removed in FIG. 2 (that is, view indicative of the state before mounting the optical semiconductor element), FIG. 4, FIG. 5 and FIG. 6 show schematic sectional views along A-A′ line, B-B′ line and C-C′ line in FIG. 2 respectively, and FIG. 7 shows a block diagram indicative of the configuration of an electric resistance value measurement means for measuring the electric resistance value of a heat-generation/heat-absorption function unit, and a heat-generation/heat-absorption amount adjustment means for adjusting the heat-generation/heat-absorption amount of the heat-generation/heat-absorption function unit based on the electric resistance value of the heat-generation/heat-absorption function unit measured by the electric resistance value measurement means.

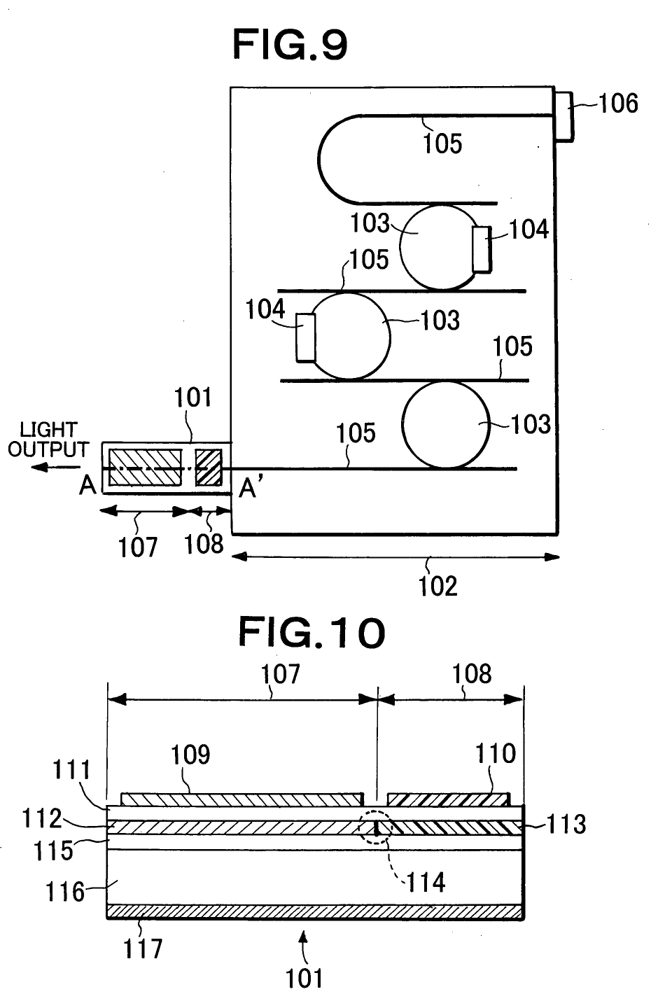

The point that the configuration in this embodiment is specifically different from the configuration of the wavelength-variable optical semiconductor device of the related technology shown in FIG. 9 and FIG. 10 is that the SOA 101 having the phase control region is used as an optical semiconductor element in the related technology, while the SOA 7 having no phase control region is used as an optical semiconductor element in this embodiment, and a heat-generation/heat-absorption function unit being a heater electrode 8, which is not provided in the related technology, is provided in this embodiment. According to the present invention, the heat-generation/heat-absorption function unit may be provided with only the heat-generation function such as the heater electrode 8, or may be provided with only the heat-absorption function, or may be provided with both the heat-generation function and heat-absorption function (for example, provided with both a heat-generation function unit and a heat-absorption function unit) The heat-generation/heat-absorption function unit heats/cools an active layer of the optical semiconductor element. In this case, “heats/cools” means at least one of “heats” and “cools”.

The configuration of this embodiment according to the present invention will be explained in detail. In this embodiment, the SOA 7 as an optical semiconductor element has an active layer 17 formed on one side surface (lower side surface in FIG. 4) of an InP substrate 14 as an element substrate. More specifically, on the lower side surface of the InP substrate 14, a lower cladding layer 16, the active layer 17, an upper cladding layer 18, and a p-electrode 19 as an element electrode of a first polarity are layered to be formed in this order. The lower cladding layer 16, active layer 17, and upper cladding layer 18 are embedded in an embedding layer 15. The lower cladding layer 16 and upper cladding layer 18 are defined such that the layer which is close to the InP substrate 14 is set to the lower layer, while the layer which is away from the InP substrate 14 is set to the upper layer. The lower cladding layer 16, active layer 17, upper cladding layer 18, and p-electrode 19 extend in a direction of the C-C′ line shown in FIG. 2 (right and left direction in FIG. 3, or direction perpendicular to the sheet surface in FIG. 4 and FIG. 5) along the lower side surface of the InP substrate 14. On the other hand, on the upper side surface of the InP substrate 14, there is formed an n-electrode 13 as an element electrode of a second polarity.

The SOA 7 is mounted on a mounting substrate unit. The mounting substrate unit has a Si substrate 23 as a mounting substrate, and the heater electrode 8 as a heat-generation/heat-absorption function unit arranged on one side surface thereof (upper side surface in FIG. 4). More specifically, on the upper side surface of the Si substrate 23, the heater electrode 8 of a required pattern is formed through an insulating layer 22. As a material for the heater electrode 8, there may be employed a platinum thin film of approximately 0.2″ m in thickness, to which the material is not restricted, and other metals or other materials may be employed so long as the metals or materials generate heat when being supplied with power. As the insulating layer 22, there may be employed a SiO₂ film of approximately 1″ m in thickness, to which the material is not restricted. On the heater electrode 8, there is formed an insulating layer 21 of a required pattern, and, on the insulating layer 21, there are formed a p-electrode 10 of a required pattern as a mounting substrate electrode of a first polarity and an n-electrode 12 of a required pattern as a mounting substrate electrode of a second polarity. As the insulating layer 21, there may be employed a SiO₂ film of approximately 1″ m in thickness, to which the material is not restricted. As the p-electrode 10 and the n-electrode 12, there may be employed an Au/Pt/Ti layered film of approximately 0.5″ m in thickness, to which the material is not restricted.

The SOA 7 is arranged such that the one side surface of the InP substrate 14 on which the active layer 17 is formed faces the one side surface of the Si substrate 23 on which the heater electrode 8 is formed. That is, the active layer 17 is so arranged as to be heated by the heater electrode 8.

As shown in FIG. 3, the heater electrode 8 is formed substantially in the shape of “U” pattern. The heater electrode 8 has a central linear extension portion that extends in parallel with the active layer 17 along the upper side surface of the Si substrate 23, and is arranged at a position corresponding to the active layer 17 or directly under the active layer 17. As shown in FIG. 2 to FIG. 4, the insulating layer 21 is formed into the pattern covering the heater electrode 8 excluding both ends thereof. As shown in FIG. 3, the p-electrode 10 is formed substantially in the shape of “L” pattern. One linear portion of the p-electrode 10 (portion extending in right and left direction in FIG. 3) extends in parallel with the central linear extension portion of the heater electrode 8, and is arranged at a position corresponding to the central linear extension portion of the heater electrode 8 or directly over the central linear extension portion of the heater electrode 8. Accordingly, the active layer 17, p-electrode 19, one linear portion of the p-electrode 10, central linear extension portion of the heater electrode 8 are so arranged as to be parallel with each other at positions corresponding to each other.

As shown in FIG. 3, on the insulating layer 21, at regions where the p-electrode 10 and n-electrode 12 are not formed, spacers 9 are formed. The spacers 9 work as bases in mounting the SOA 7 onto the mounting substrate unit, and keep the clearance between the upper surface of the insulating layer 21 of the mounting substrate unit and the lower surface of the embedding layer 15 of the SOA 7 constant with a predetermined value. As the spacer 9, there may be employed a SiO₂ film of approximately 10″ m in thickness and approximately 10 to 70″ m×10 to 70″ m in lengthwise and crosswise dimension, to which the material is not restricted.

As shown in FIG. 4 to FIG. 6, one linear portion of the p-electrode 10 (portion extending right and left direction in FIG. 3) of the mounting substrate unit and the p-electrode 19 of the SOA 7 are bonded to each other using a conductive fusion bonding member 20 as a bonding member. Accordingly, the SOA 7 and the mounting substrate unit are bonded to each other. As the conductive fusion bonding member 20, there may be employed an Au—Sn solder film of approximately 1 to 10″ m in thickness, to which the material is not restricted.

As has been described above, in this embodiment, the SOA 7 is mounted on the mounting substrate unit under the p-side down configuration with the p-electrode 19 directed downward.

As shown in FIG. 2, the n-electrode 13 of the SOA 7 is connected to the n-electrode 12 of the mounting substrate unit by a bonding wire 11. As shown in FIG. 2, the end portion of the other linear portion of the p-electrode 10 (portion extending in up and down direction in FIG. 2 and FIG. 3) of the mounting substrate unit and the n-electrode 12 are exposed, to which a circuit for driving the SOA 7, not shown, is connected by the wire bonding etc.

To both the exposed ends of the heater electrode 8, a control circuit 26 shown in FIG. 7 is connected by the wire bonding, etc. The control circuit 26 works also as the heat-generation/heat-absorption amount adjustment means for adjusting the heat-generation/heat-absorption amount of the heater electrode 8. The control circuit 26 makes the heater electrode 8 generate heat by applying a voltage to the heater electrode 8 using a variable power supply 30. The control circuit 26 is provided with an ammeter 27, a voltmeter 28, and a control unit 29 that controls the variable power supply 30 to adjust the heat generation amount of the heater electrode 8 based on the measurement result by the ammeter 27 and voltmeter 28.

In this embodiment, by applying a voltage, the heater electrode 8 is made to generate heat, which heat changes the temperature of the SOA 7, especially the active layer 17. At this time, due to change of the refraction index based on temperature change of a semiconductor configuring the SOA 7, the phase of a light guided by the SOA 7 is made to fluctuate. That is, in this embodiment, by controlling the heat generation amount of the heater electrode 8, it becomes possible to control the phase of a light so that the most favorable oscillation characteristics can be obtained as a wavelength-variable light source. At this time, the required temperature change width is approximately 10 K or lower in case of a general long wavelength band SOA. In this embodiment, since the active layer 17 of the SOA 7 is arranged in close proximity to the heater electrode 8 of the mounting substrate unit, by controlling the application of power to the heater electrode 8, the temperature of the active layer 17 of the SOA 7 can be effectively adjusted.

In the control circuit 26 that controls the heat generation amount of the heater electrode 8, a current flowing through the heater electrode 8 and a voltage applied to the heater electrode 8 are measured by the ammeter 27 and voltmeter 28, and an output voltage of the variable power supply 30 is controlled by the control unit 29 based on the measurement result so that the electric power for the heater electrode 8 comes to be of a desirable value. Otherwise, since the resistance value of the heater electrode 8 has one-to-one relation with the temperature thereof, calculating the resistance value of the heater electrode 8 from the voltage applied to the both ends of the heater electrode 8 and the current flowing through the heater electrode 8, an output voltage of the variable power supply 30 may be controlled so that the resistance value comes to be of a desirable value. In this case, the control unit 29 works also as the electric resistance value measurement means that measures the electric resistance value of the heater electrode 8.

In this embodiment, the mounting substrate unit has a ring resonator type wavelength filter as an optical circuit provided with the reflection function of returning a light emitted from the SOA 7 to the SOA 7. The ring resonator type wavelength filter is arranged on one side surface of the Si substrate 23 as a mounting substrate on which the heater electrode 8 is formed (upper side surface in FIG. 6).

That is, as shown in FIG. 1 and FIG. 6, the mounting substrate unit of the optical semiconductor device in this embodiment uses the Si substrate 23 as a common mounting substrate, and a semiconductor optical amplifier (SOA) mounting unit 6 for mounting the SOA 7 is set to the first region, while a ring resonator type wavelength filter unit 1 where the ring resonator type wavelength filter is formed is set to the second region.

The ring resonator type wavelength filter in this embodiment includes, similar to the wavelength-variable optical semiconductor device of the related technology shown in FIG. 9 and FIG. 10, a plurality of ring resonators 2 whose optical path lengths are slightly different from each other, heaters 3 which control the temperature of the ring resonators 2, connection waveguides 4 which connect the ring resonators 2 serially or which are connected to both end ring resonators 2, and a high reflection film 5 which is arranged at the end of the first end connection waveguide 4. In order to control the temperature of the ring resonators 2, a cooling means may be employed instead of the heaters 3. The ring resonator type wavelength filter is an optical circuit provided with a function of returning, among lights coming from the SOA 7 to the end of the second end connection waveguide 4 located at the opposite side of the first end connection waveguide 4, only a light of a selected specific wavelength to the SOA mounting unit 6. This selection of specific wavelength can be controlled by the heaters 3. That is, the heaters 3 work as means for controlling “selected wavelength”. Accordingly, the ring resonator type wavelength filter is provided with the reflection function only for a light of a selected wavelength. The details of the ring resonator type wavelength filter unit 1 are disclosed in the Non-patent Document 1, and explanation of the ring resonator type wavelength filter unit is omitted here.

The method of forming the mounting substrate unit of the optical semiconductor device in this embodiment will be explained briefly. Firstly, by employing the CVD method, a SiO₂ lower cladding layer 25 of approximately 10″ m in thickness and a SiON layer of approximately 2″ m in thickness are formed on the Si substrate 23. Employing the general photolithography process and dry etching process, the SiON layer is worked to be of a required pattern so as to form the connection waveguides 4 and ring resonators 2. Next, a SiO₂ upper cladding layer 24 of approximately 10″ m in thickness is formed. Subsequently, by employing the dry etching process, the SiO₂ upper cladding layer 24, SiON layer, and SiO₂ lower cladding layer 25 of the SOA mounting unit 6 are etched to be removed. Then, on the SOA mounting unit 6, the insulating layer 22, heater electrode 8, insulating layer 21, p-electrode 10, n-electrode 12, and spacers 9 are formed by employing the general film forming process, photolithography process, and dry etching process. Furthermore, on the ring resonator type wavelength filter unit 1, the heaters 3 are formed by employing the general film forming process, photolithography process, and dry etching process.

On the other hand, the SOA 7 of required dimensions is produced by employing the general optical semiconductor element production method. Then, thus produced SOA 7 is mounted onto the mounting substrate unit. At this time, one linear portion of the p-electrode 10 (portion extending right and left direction in FIG. 3) of the mounting substrate unit and the p-electrode 19 of the SOA 7 is bonded to each other using the conductive fusion bonding member 20.

In the wavelength-variable optical semiconductor device of the related technology shown in FIG. 9 and FIG. 10, the phase control region 108 for the SOA is arranged so as to control the phase of a light, and a current is applied thereto. On the other hand, according to the embodiment of the present invention, the phase control region for the SOA becomes unnecessary, which brings about an effect of solving problems of the instability in oscillation characteristics due to the reflection of light at the butt joint which arises from the existence of the phase control region and the high production cost due to the low yield ratio of the butt joint.

Next, the second embodiment of an optical semiconductor device provided with the phase control function according to the present invention will be explained. FIG. 8 shows a schematic sectional view indicative of the configuration of the second embodiment of an optical semiconductor device provided with the phase control function according to the present invention, which corresponds to FIG. 6 showing the first embodiment. In FIG. 8, parts or components similar to those shown in FIG. 1 to FIG. 7 are indicated with the same reference numerals.

In the first embodiment, the SOA mounting unit 6 and the ring resonator type wavelength filter unit 1 are formed on the common Si substrate 23. On the other hand, in the second embodiment, as a substrate for the ring resonator type wavelength filter unit 1, an additional substrate 23 which is different from a mounting substrate 31 for the SOA mounting unit 6 is used. As the additional substrate 23, the Si substrate 23 can be used. The end surface of the Si substrate 23 and the end surface of the mounting substrate 31 are bonded to each other by an adhesive agent 32.

The operation and effect of the second embodiment will be explained. In the first embodiment, in mounting the SOA onto the mounting substrate unit and taking the alignment between the SOA and the connection waveguides of the ring resonator type wavelength filter unit, the temperature of the conductive fusion bonding member 20 and the vicinity thereof gets to the melting point of the conductive fusion bonding member 20 or more (generally, approximately 300° C. or more) or more. On the other hand, in the second embodiment, even if there is raised a similar temperature rise in mounting the SOA 7 onto the SOA mounting substrate 31, afterward, in bonding the SOA mounting substrate 31 to the Si substrate 23 and taking the alignment between the SOA 7 and the connection waveguides 4 of the ring resonator type wavelength filter unit 1, there is required no temperature rise. Accordingly, with the SOA 7 emitting light, it becomes possible to fix the SOA mounting substrate 31 and the Si substrate 23 to each other by alignment while monitoring the optical coupling state between the SOA 7 and the connection waveguides 4 using an optical power meter etc., which can realize fixing by alignment with higher accuracy. As the adhesive agent 32, a UV cure adhesive that is cured when being irradiated by an ultraviolet ray can be used. In this case, as a material for the SOA mounting substrate 31, it is desirable to select a material through which an ultraviolet ray can be transmitted such as glass. The operation and effect obtained in the first embodiment can be similarly obtained in the second embodiment.

In the second embodiment, as a means to fix the SOA mounting substrate 31 to the Si substrate 23, an adhesive agent is used, to which the fixing means is not restricted, and other means or methods may be employed so long as the SOA mounting substrate 31 and the Si substrate 23 can be fixed to each other with the relative position thereof adjusted. For example, there may be employed a method in which the SOA mounting substrate 31 and the Si substrate 23 are fixed in advance to metal jigs, respectively, and the metal jigs are welded to be fixed by irradiating a YAG laser etc.

In the first and second embodiments, on the mounting substrate unit, the heater electrode 8 is arranged under the p-electrode 10 through the insulating layer 21, to which the configuration is not restricted, and similar effects can be obtained so long as the configuration in which the heat-generation/heat-absorption function unit such as the heater electrode 8 is arranged in close proximity to the active layer of the optical semiconductor element is employed.

In the first and second embodiments, the SOA 7 and the connection waveguides 4 are directly coupled optically, to which the connection manner is not restricted, and a gel agent to improve the coupling characteristics such as a translucent synthetic resin may be infused therebetween. Otherwise, there may be inserted an optical lens therebetween.

In the first and second embodiments, the SOA is used as the optical semiconductor element, to which the optical semiconductor element is not restricted, and other optical semiconductor elements such as a semiconductor laser may be employed.

In the first and second embodiments, the ring resonator type wavelength filter is used as the wavelength filter, to which the wavelength filter is not restricted, and other wavelength filters employing other principles may be employed.

In the first and second embodiments, the optical semiconductor device is applied to the wavelength-variable light source, to which the application is not restricted, and similar effects can be obtained in case the optical semiconductor device is applied to other optical devices which have to control the phase of a light.

The optical semiconductor device of the present invention can be used as an optical communication light source, especially as a wavelength-variable light source for a WDM transmission system.

What is claimed is:

1. An optical semiconductor device comprising:
an optical semiconductor element; and
a mounting substrate unit on which the optical semiconductor element is mounted,
wherein the optical semiconductor element has an element substrate and an active layer formed on one side surface of the element substrate, the mounting substrate unit has a mounting substrate and a heat-generation/heat-absorption function unit arranged on one side surface of the mounting substrate, and the optical semiconductor element is arranged such that the one side surface of the element substrate on which the active layer is formed faces the one side surface of the mounting substrate on which the heat-generation/heat-absorption function unit is arranged, and the active layer is to be heated/cooled due to the heat-generation/heat-absorption by the heat-generation/heat-absorption function unit.

2. The optical semiconductor device claimed in claim 1, wherein the optical semiconductor element is bonded to the mounting substrate unit.

3. The optical semiconductor device claimed in claim 1, further comprising a spacer arranged between the optical semiconductor element and the mounting substrate unit.

4. The optical semiconductor device claimed in claim 1, wherein the heat-generation/heat-absorption function unit is formed of a metal thin film.

5. The optical semiconductor device claimed in claim 1, wherein the active layer extends along the one side surface of the element substrate, the heat-generation/heat-absorption function unit has an extension portion that extends along the one side surface of the mounting substrate, and the active layer and the extension portion of the heat-generation/heat-absorption function unit have their extension directions made parallel with each other and are arranged at positions corresponding to each other.

6. The optical semiconductor device claimed in claim 5, wherein the mounting substrate unit comprises an insulating layer formed on the heat-generation/heat-absorption function unit, and amounting substrate electrode of a first polarity formed on the insulating layer.

7. The optical semiconductor device claimed in claim 6, wherein the mounting substrate electrode of the first polarity has a portion that extends in parallel with the extension portion of the heat-generation/heat-absorption function unit.

8. The optical semiconductor device claimed in claim 7, wherein the optical semiconductor element comprises a lower cladding layer formed on the one side surface of the element substrate, the active layer being formed on the lower cladding layer, and an upper cladding layer formed on the active layer, and an element electrode of a first polarity formed on the upper cladding layer so as to extend in parallel with the active layer, and wherein the element electrode of the first polarity and the mounting substrate electrode of the first polarity are bonded to each other using a conductive bonding member.

9. The optical semiconductor device claimed in claim 1, further comprising a heat-generation/heat-absorption amount adjustment means for adjusting the heat-generation/heat-absorption amount of the heat-generation/heat-absorption function unit.

10. The optical semiconductor device claimed in claim 9, wherein the heat-generation/heat-absorption amount adjustment means is provided with an electric resistance value measurement means for measuring the electric resistance value of the heat-generation/heat-absorption function unit, and adjusts the heat-generation/heat-absorption amount of the heat-generation/heat-absorption function unit based on the electric resistance value of the heat-generation/heat-absorption function unit measured by the electric resistance value measurement means.

11. The optical semiconductor device claimed in claim 1, wherein the mounting substrate unit has an optical circuit provided with a reflection function of returning a light emitted from the optical semiconductor element to the optical semiconductor element.

12. The optical semiconductor device claimed in claim 11, wherein the optical circuit is provided with the reflection function only for a light of a selected wavelength.

13. The optical semiconductor device claimed in claim 12, wherein the mounting substrate unit is provided with a means for controlling the selected wavelength.

14. The optical semiconductor device claimed in claim 11, wherein the optical circuit is formed on the mounting substrate.

15. The optical semiconductor device claimed in claim 11, wherein the optical circuit is formed on an additional substrate different from the mounting substrate, and the additional substrate is bonded to the mounting substrate.

16. The optical semiconductor device claimed in claim 1, wherein the mounting substrate is a silicon substrate.
